(19) United States
(12) Patent Application Publication
(10) Pub. No.: US 2025/0324749 A1
(43) Pub. Date: Oct. 16, 2025

(54) Reduction of the Floating Body Effect in N-Type MOSFET Devices

(71) Applicant: pSemi Corporation, San Diego, CA (US)

(72) Inventors: Jagar Singh, New York, NY (US); Waleed Asadi, Oceanside, CA (US); Nijita Kesavan, San Diego, CA (US); Sonja Nedeljkovic, Windsor, CO (US)

(21) Appl. No.: 18/631,597

(22) Filed: Apr. 10, 2024

(51) Int. Cl. H01L 27/088; H01L 29/66; H01L 29/78

(52) U.S. Cl. CPC H10D 84/84; H10D 30/0281; H10D 30/65; H10D 30/711

(57) ABSTRACT

Novel NEDMOS and/or LDMOS FET integrated circuit structures that reduce or eliminate the floating body effect by reducing the built-in voltage Vbi of the device. Reduction of Vbi includes adding a source-side structure that includes a “Vbi Reduction Material” (VRM) layer. VRM has a bandgap less than the bandgap of Si and, for an N-type device, a valence band that is higher than the valence band of the body material. The low Vbi of the VRM layer on the source-side of a MOSFET device that would otherwise exhibit a floating body effect allows significantly freer movement of holes from the body of the device towards the source region, thus increasing body hole collection efficiency, and significantly reduces the floating body effect.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products—including laptop computers, mobile telephones, and electric cars—utilize MOSFET-based integrated circuits (ICs). A number of architectural variations exist for MOSFETs. The most common type of MOSFETs are N-type MOSFETs (NFETs), which have N+ doped source and drain regions abutting opposite sides of a channel region, which, for an enhancement-mode device, may be doped with P-type material or be intrinsic silicon. For example, N-type Extended Drain MOS (NEDMOS) FETs fabricated using silicon-on-insulator (SOI) processes are common transistor devices capable of handling relatively high drain voltages. The high-voltage characteristics of NEDMOS FETs improves device reliability.

A problem with some types of MOSFETs is the floating body effect (FBE), particularly NFETs (including NEDMOS FETs) fabricated using SOI technology. The FBE is the effect of dependence of the body potential of certain N-type MOSFETs on the history of its biasing and the carrier recombination processes. More particularly, the body of an SOI MOSFET forms a capacitor with respect to the insulated substrate, the insulated gate, and the source and drain regions. For example, FIG. 1 is a stylized depiction of an SOI MOSFET 100. In the illustrated example, the body 102 is sandwiched between a source region 104 and a drain region 106 horizontally. Vertically, the body 102 is sandwiched between a gate oxide (GOX) layer 108 and a gate 110 on a top side, and between a buried oxide (BOX) layer 112 and a substrate 114 on a bottom side. Schematic capacitors C and corresponding parallel diodes D are shown with respect to a floating body 116 of charge and the source 104, drain 106, gate 110, and substrate (114).

Charge accumulated within the floating body 116 may cause adverse effects, for example, opening of parasitic transistors in the structure and causing off-state leakages, resulting in higher current consumption. The FBE also causes a history effect, the dependence of the threshold voltage (V_{TH}) of the transistor on its previous states. In analog devices, the FBE is also known as the kink effect.

Another problem with high-voltage NFETs in general is increased hot carrier injection (HCI) due to higher drain voltages. HCI is a phenomenon where a charge carrier (an electron in the case of NMOS devices) gains sufficient kinetic energy to overcome a potential barrier necessary to break an interface state. The charged carriers can become trapped in the gate dielectric of a MOSFET and may permanently change the switching characteristics of the device. HCI is one of the mechanisms that adversely affects the reliability of MOSFETs.

The present invention is directed to novel N-type MOSFETs capable of withstanding relatively high drain voltages while effectively reducing—and even eliminating—the floating body effect.

### SUMMARY

The present invention encompasses novel integrated circuit structures that reduce or eliminate the floating body effect (FBE) by reducing the built-in voltage Vbi of the device. Reduction of Vbi includes adding a source-side structure that includes a “Vbi Reduction Material” (VRM) layer. VRM has a bandgap less than the bandgap of Si and, for an N-type device, a valence band that is higher than the valence band of the body material. The low Vbi of the VRM layer on the source-side of an N-type MOSFET device that would otherwise exhibit an FBE allows significantly freer movement of holes from the body of the device towards the source region, thus increasing body hole collection efficiency and significantly reducing the floating body effect.

A source-side VRM layer may be usefully added to Laterally-Diffused MOS (LDMOS) FETs fabricated using bulk silicon. NEDMOS FETs and/or LDMOS FETs may be fabricated as enhancement mode devices or depletion mode devices. A NEDMOS or LDMOS device fabricated in accordance with the present invention may be combined with a P-type MOSFET to provide a high-voltage Complementary-MOS (CMOS) device pair.

One embodiment of the present invention includes an N-type EDMOS FET including an active layer that includes a body region having a source-side edge and a drain-side edge, a source region adjacent the source-side edge of the body region, the source region including at least one layer of Si and at least one layer of a built-in voltage (Vbi) reduction material, a drift region having a first side adjacent the drain-side edge of the body region, and having a second side, and a drain region adjacent the second side of the second drift region.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1 is a stylized depiction of an SOI MOSFET.

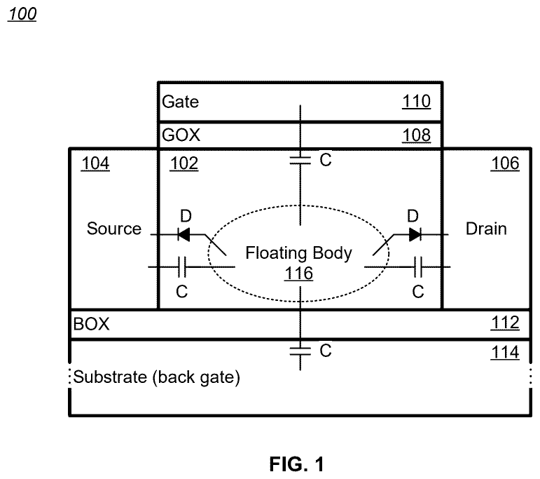

FIG. 2A is a stylized cross-sectional view of an SOI IC structure for a first NEDMOS FET in accordance with the present invention.

FIG. 2B is a stylized cross-sectional view of an SOI IC structure for a second NEDMOS FET in accordance with the present invention.

FIG. 2C is a stylized cross-sectional view showing selected elements of the NEDMOS FET of FIG. 2A.

FIG. 2D is a stylized plan view of a first variation of the NEDMOS of FIG. 2A.

FIG. 2E is a stylized plan view of a second variation of the NEDMOS of FIG. 2A.

FIG. 3A is a stylized cross-sectional view of a portion of an SOI IC structure for a second NEDMOS FET in accordance with the present invention.

FIG. 3B is a stylized cross-sectional view of a NEDMOS structure in accordance with the present invention taken along line X1-X1 of FIG. 3A.

FIG. 3C is a stylized cross-sectional view of a NEDMOS structure in accordance with the present invention taken along line X2-X2 of FIG. 3A.

FIGS. 4A-4C are stylized cross-sectional view showing various stages of one method of fabricating the VRM layer within the active layer of a NEDMOS FET.

FIG. 5 is a process flowchart 500 showing one process that is suitable for some contemporary IC front-end-of-line (FEOL) foundries.

FIG. 6 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses novel integrated circuit structures that reduce or eliminate the floating body effect (FBE) by reducing the built-in voltage Vbi of the device. Vbi is the difference of the Fermi levels in P-type and N-type semiconductors before they are joined. Reduction of Vbi includes adding a source-side structure that includes a “Vbi Reduction Material” (VRM) layer. VRM has a bandgap less than the bandgap of Si and, for an N-type device, a valence band that is higher than the valence band of the body material. The low Vbi of the VRM layer on the source-side of an N-type MOSFET device of the type that would otherwise exhibit an FBE allows significantly freer movement of holes from the body of the device towards the source region, thus increasing body hole collection efficiency and significantly reducing the floating body effect.

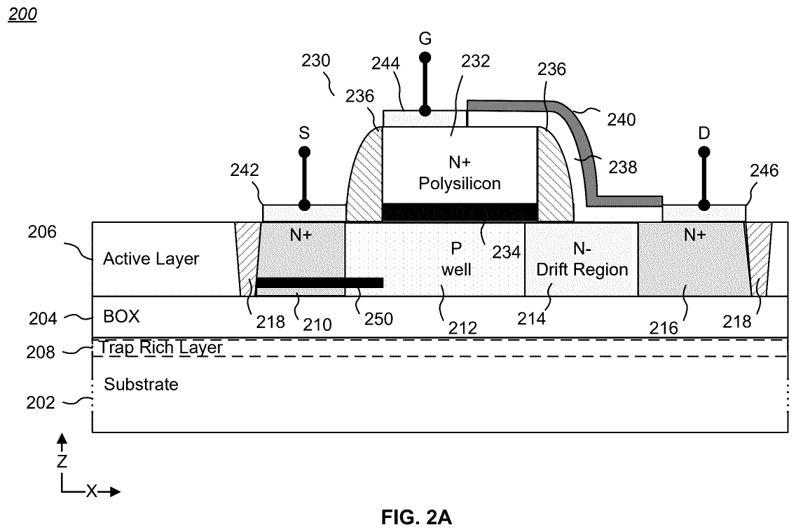

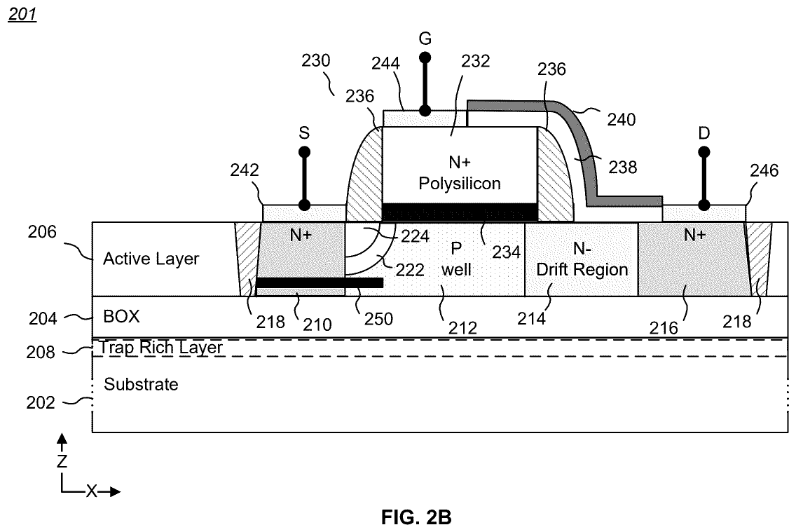

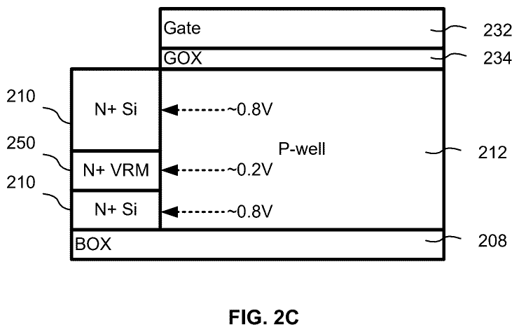

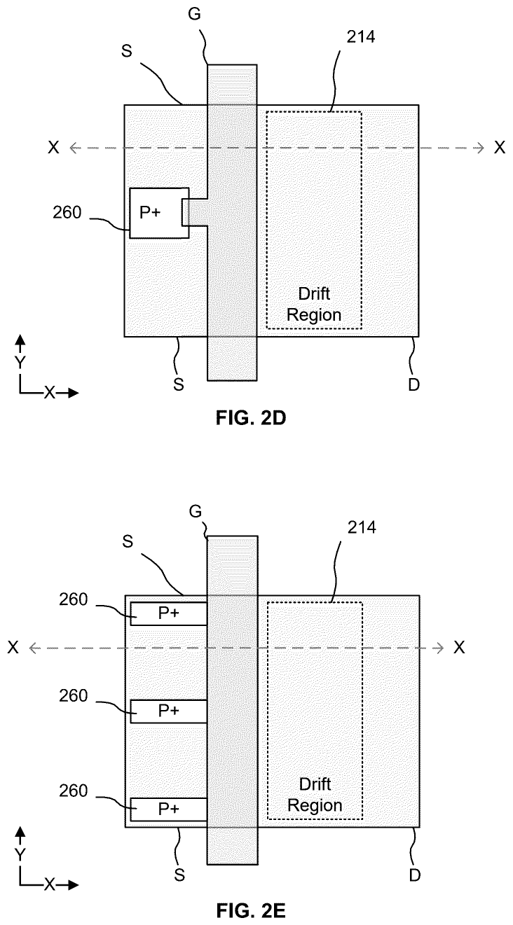

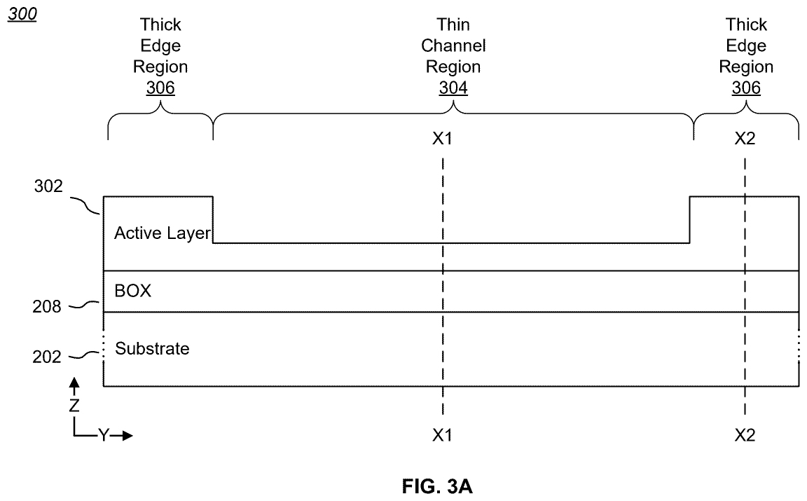

FIG. 2A is a stylized cross-sectional view of an SOI IC structure for a first NEDMOS FET 200 in accordance with the present invention. The SOI structure includes a substrate 202, a buried-oxide (BOX) insulator layer 204, and an active layer 206 (note that the dimensions for the elements of the SOI IC structure are not to scale; some dimensions have been exaggerated for clarity or emphasis). The active layer may be crystalline Si or any other suitable semiconductor. The substrate 202 is typically a semiconductor material such as silicon, but may be other materials such as glass or sapphire. The BOX layer 204 is a dielectric and is often SiO₂ formed as a “top” surface of the substrate 202; for some substrates (e.g., glass or sapphire), a BOX layer 204 optionally may be omitted. Some embodiments may include a trap-rich layer 208 (shown in dashed outline) between the BOX layer 204 substrate 202. A trap-rich layer 208 mitigates parasitic surface conduction and improves device performance at high frequencies.

The active layer 206 may include some combination of implants and/or layers that include dopants, dielectrics, polysilicon, conductors, passivation, and other materials to form active and/or passive electronic components and/or mechanical structures. For example, FIG. 2A shows the NEDMOS FET 200 having an active layer 206 that includes an N+ source 210, a P-type body region or “P-well” 212 in which an electrically conductive channel can be formed, an N− Si drift region 214, and an N+ drain 216, all bounded by an isolation structure 218, such as a shallow trench isolation (STI) structure. The designation “P− means a lesser concentration of P-type dopant (e.g., boron) than the designation “P+”. In some embodiments, the body region may actually be intrinsic Si.

FIG. 2B is a stylized cross-sectional view of an SOI IC structure for a second NEDMOS FET 201 in accordance with the present invention. Similar in most aspects to FIG. 2A, the second NEDMOS FET 201 includes optional features within the active layer 206, specifically a halo region 222 and a lightly-doped drain (LDD) region 224 (“LDD” being somewhat of a misnomer, since the LDD region 224 is only on the source-side in the example embodiments of the present invention). A halo implant mitigates punch-through while an LDD region mitigates avalanche breakdown. More specifically, the halo region 222 increases a sub-surface electric field to reduce so-called punch-through, or short channel, conduction between the source 210 and the drain 216, thus increasing the channel breakdown voltage. The LDD region 224 extends the source 210 underneath a gate structure 230 and modulates the threshold voltage V_{TH}, transconductance Gm, and leakage current of the device.

Referring to both FIG. 2A and FIG. 2B, the gate structure 230 is formed in contact with a surface of the active layer 206, between the source 210 and the drain 216. The gate structure 230 includes a conductive layer 232, such as N+ doped polysilicon, in contact with an insulating gate oxide (GOX) layer 234, the thickness of which may be varied for different applications. In the illustrated example, the gate structure 230 is surrounded by insulating spacers 236. In the illustrated example, part of the gate structure 230 and the N− drift region 214 are coated with a dielectric 238, such as SiO₂, Si₃N₄, etc., which in turn is overlaid with a salicide block (SAB) layer 240, such as silicon nitride (SiN), to prevent subsequent formation of silicide on those structures/regions.

A conductive source contact 242, a conductive gate contact 244, and a conductive drain contact 246, which may be self-aligned silicides (also known as “salicides”), are respectively formed in contact with the source 210, the gate structure 230, and the drain 216, except in areas where silicide formation may be blocked. Stylized electrical terminals S, G, and D are shown coupled to the corresponding source contact 242, gate contact 244, and drain contact 246.

The gate structure 230, the BOX layer 204, and the active layer 206 (which may include multiple FETs) may be collectively referred to as a “device region” or “substructure” for convenience (noting that other structures or regions may intrude into the substructure in particular IC designs). A superstructure (not shown) of various elements, regions, and structures may be fabricated on or above the substructure in order to implement particular functionality. The superstructure may include, for example, conductive interconnections from the illustrated FET 200 to other components (including other FETs on the same IC die) and/or external contacts, passivation layers, and protective coatings.

Key to embodiments of the present invention is the addition on the addition of a VRM layer 250 on the source-side of the gate structure 230. The VRM layer 250 forms part of the source regions 210 but may extend further into the P-well 212. The VRM layer 250 may comprise germanium (Ge), heterogeneous or homogenous SiGe alloys (including Ge-doped Si, graded Ge and Si mixtures, or the like), heterogeneous or homogenous indium arsenide (InAs) alloys, and similar materials having a bandgap less than the bandgap of silicon (about 1.12 eV for Si) and, for an N-type device, a valence band that is higher than the valence band of the body material. For example, the Vbi of a Ge/Si junction is typically about 0.2V, with SiGe/Si junctions having intermediate values of Vbi between about 0.2V and about 0.8V (the typical Vbi of pure Si/Si junctions in an integrated circuit).

FIG. 2C is a stylized cross-sectional view showing selected elements of the NEDMOS FET 200 of FIG. 2A. In the illustrated example, the N+ Si portion of the source 210 is in two parts, upper and lower, sandwiching an N+ VRM layer 250 (in other embodiments, the VRM layer 250 may be below all of the Si or above all of the Si). In this example, the VRM layer 250 comprises N+ Ge, which is preferably located between upper and lower N+ Si layers to better collect or sweep away holes from the body region of the FET. The body of the MOSFET—the P-well 212—thus experiences different Vbi values with respect to the N+ Si portion of the source 210 and the VRM layer 250. The bandgap of the P-well 212 (which may be intrinsic Si) is greater than the bandgap of either N+ Si or N+ VRM. Accordingly, in the illustrated example, for the N+ Si portions of the source 210, the Vbi is about 0.8V, while for the N+ Ge VRM layer 250, the Vbi is about 0.2V.

The low Vbi caused by the VRM layer 250 on the source-side of the device allows significantly freer movement of holes from the P-well 212 towards the source region, thus increasing body hole collection efficiency and significantly reducing the FBE. In preferred embodiments, the VRM layer 250 may range in thickness (in the Z dimension) from about 20 Å to about 400 Å.

It may be noted that in conventional MOSFETs, lowering Vbi causes higher leakage (Idoff), which was a concern in many circuit designs. However, since the extended drift region of NEDMOS devices essentially provides a long channel, Idoff is much less of a concern. Lower Vbi at the source 210 is much less concern than lower Vbi at the drain 216, so lowering Vbi at the source 210 is not a major issue.

FIG. 2D is a stylized plan view of a first variation of the NEDMOS 100 of FIG. 2A. FIG. 2E is a stylized plan view of a second variation of the NEDMOS 100 of FIG. 2A. Contacts have been omitted to avoid clutter. The cross-sectional view of NEDMOS 100 in FIG. 2A may be considered to have been taken along line X-X in either FIG. 2D or FIG. 2E. Both figures show a P+ body contact region 260 that connects through the source S downward to and in contact with the P-well 212 and serves to collect holes from the P-well 212. In many embodiments, it is useful to have more than one P+ body contact region 260 (as in FIG. 2E) to improve the efficiency of hole collection.

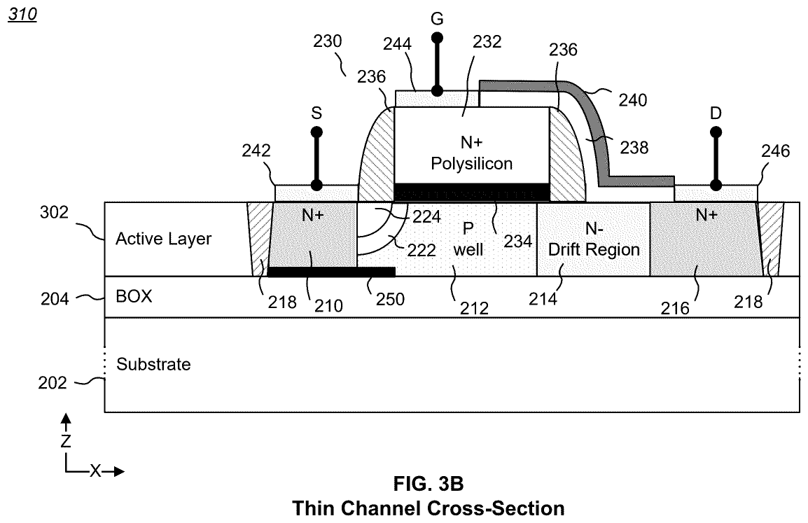

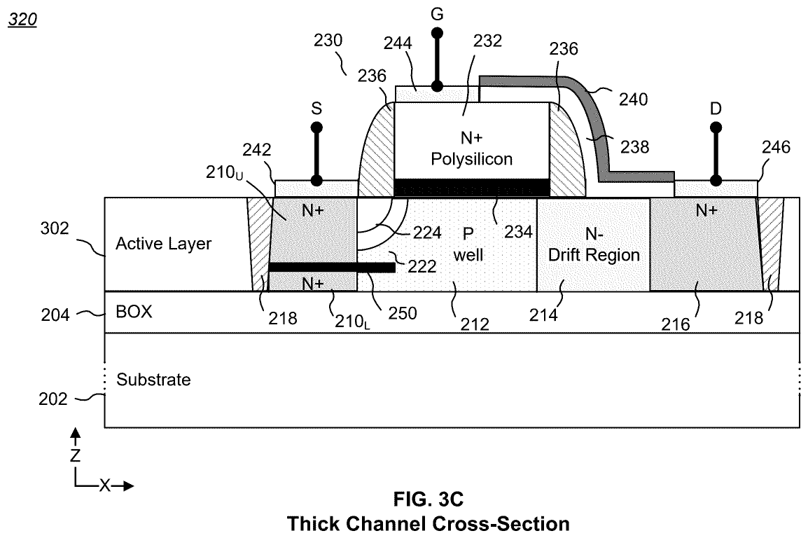

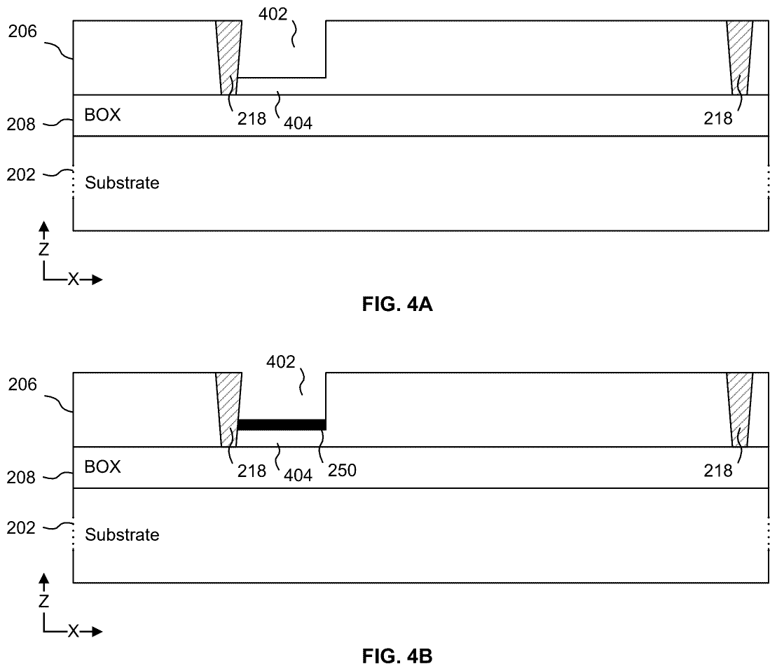

FIG. 3A is a stylized cross-sectional view of a portion of an SOI IC structure for a second NEDMOS FET 300 in accordance with the present invention. In the illustrated example, the active layer 302 has been processed to produce a thin channel region 304 and abutting thick edge regions 306. The illustrated structure may be fabricated, for example, by using subtractive techniques (e.g., by starting with a thick active layer 302, masking the thick edge regions 306, and etching the thin channel region 304) or by using additive techniques (e.g., by starting with a thin active layer 302, masking the thin channel region 304, and epitaxially growing the thick channel regions 306). The NEDMOS structure described above with respect to FIG. 2A may then be fabricated, although the X-Z cross-section will differ between the thin channel region 304 and the thick edge regions 306. For example, FIG. 3B is a stylized cross-sectional view of a NEDMOS structure 310 in accordance with the present invention taken along line X1-X1 of FIG. 3A. The VRM layer 250 is shown as being between the BOX layer 204 and the N+ source 210. In contrast, FIG. 3C is a stylized cross-sectional view of a NEDMOS structure 320 in accordance with the present invention taken along line X2-X2 of FIG. 3A. The VRM layer 250 is shown as being spaced from the BOX layer 204 and midway between a lower portion of the N+ source 210L and an upper portion of the N+ source 210u owing to the greater thickness of the active layer 302 in the thick edge regions 306.

A VRM layer 250 may be usefully added to Laterally-Diffused MOS (LDMOS) FETs fabricated using bulk silicon. A bulk semiconductor IC LDMOS structure has an architecture similar to the example NEDMOS of FIG. 2A but omits the BOX layer 204. There are typically other differences, most notably that the N− drift region 214 typically surrounds the N+ drain 216 and generally extends beneath the drain. In addition, any substrate contact may be modified and placed at a different location.

Note also that while the examples of embodiments of the present invention depict NEDMOS FETs, the inventive aspects of the present disclosure may be applied to any type of transistor device that exhibits a floating body effect, including MOSFETs in general and LDMOS devices. Further, such transistor devices may be fabricated as enhancement mode devices or depletion mode devices. A NEDMOS device or LDMOS device fabricated in accordance with the present invention may be combined with a P-type MOSFET to provide a high-voltage Complementary-MOS (CMOS) device pair.

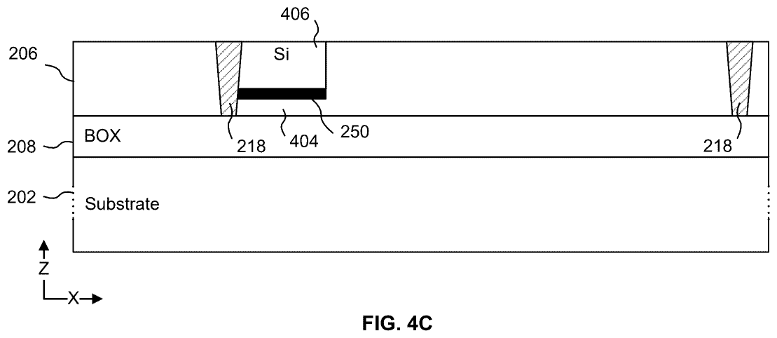

A number of different processes may be used to fabricate the IC architectures disclosed above. For example, FIGS. 4A-4C are stylized cross-sectional view showing various stages of one method of fabricating the VRM layer 250 within the active layer 206 of a NEDMOS FET.

FIG. 4A shows that a portion of the active layer 206 has been masked and etched to create a void 402. In the illustrated example, a portion 404 of the active layer 206 remains beneath the void 402, due to limiting the depth of etching. However, in other embodiments, the void 402 may be etched down to the BOX layer 208.

FIG. 4B shows that a VRM layer 250 has been formed within the void 404, such as by deposition or epitaxial growth of the Vbi Reduced Material (e.g., Ge, SiGe, or InAs), preceded by suitable masking to avoid formation of the VRM outside of the void 404.

FIG. 4C shows that Si 406 has been formed within the remaining portion of the void 404, such as by deposition or epitaxial growth, preceded by suitable masking to avoid formation of the Si outside of the void 404. The structure at this point may be planarized (e.g., by chemical-mechanical polishing, CMP) and the remaining elements of the NEDMOS device may be formed.

It should be appreciated that more than one VRM layer 250 may be formed within the source “stack” by forming alternating layers of VRM and Si.

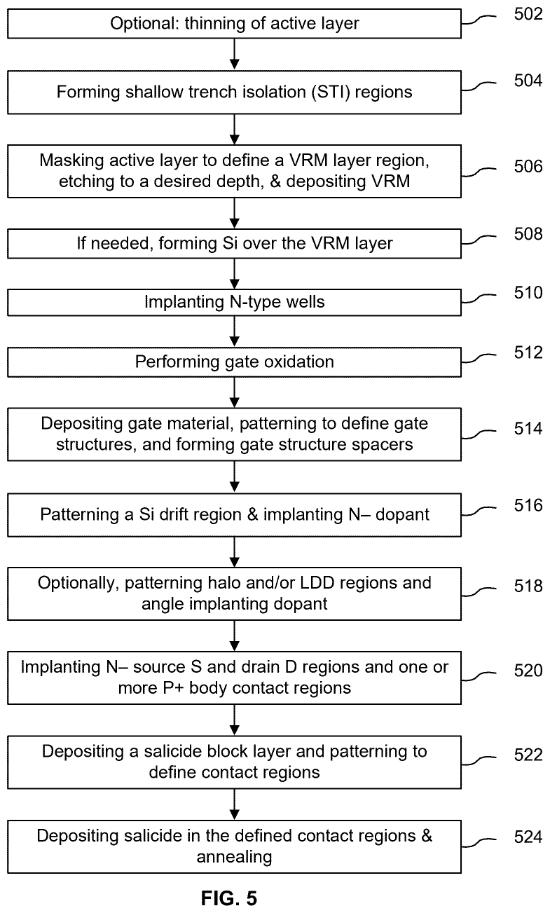

FIG. 5 is a process flowchart 500 showing one process that is suitable for some contemporary IC front-end-of-line (FEOL) foundries. Note that some conventional steps, such as planarization, passivation, details of masking and etching, and superstructure formation have been omitted as known to those of ordinary skill in the art. The illustrated process includes:
(1) If needed, thinning the semiconductor active layer formed on a substrate to a suitable thickness (Step 502). In some cases, selective thinning (or alternatively, selective build up) of Si may be performed for embodiments of the type shown in FIGS. 3A-3C.
(2) Forming shallow trench isolation (STI) regions (Step 504).
(3) Masking the Si active layer to define a region in which the VRM layer 250 is to be formed, etching the defined region to a desired depth, and depositing Vbi Reduction Material within the etched region (Step 506).
(4) If the VRM layer 250 is not to be the top layer of the source, then forming Si over the VRM layer 250, such as by epitaxial growth (Step 508).
(5) Implanting N-type wells (Step 510).
(6) Performing gate oxidation (Step 512).
(7) Depositing gate material (e.g., P+ poly-Si), patterning (e.g., masking and etching) to define gate structures, and forming gate structure spacers (Step 514).
(8) Patterning a Si drift region 214 and implanting N− dopant (which may be implanted at an angle so as to extend under the drain-side edge of the gate material) (Step 516).
(9) Optionally, patterning halo and/or LDD regions and angle dopant (which may be implanted at an angle so as to extend under the source-side edge of the gate material) (Step 518).
(10) Implanting N+ source S and drain D regions and one or more P+ body contact regions (Step 520). Note that in this embodiment, the VRM layer 250 will be doped when the source 210 is doped.
(11) Depositing a salicide block layer and patterning to define contact regions (Step 522).
(12) Depositing salicide (e.g., NiSi) in the defined contact regions and annealing (Step 524).

As should be appreciated, other “recipes” that include additive and/or subtractive process steps may be used to fabricate essentially the same NEDMOS structures of the type described in this disclosure. For example, a NEDMOS device may be fabricated up to the point of fabricating the gate structure 230 but without the VRM layer 250. The structure may then be etched on the source-side of the gate structure 230 can be etched to form a void into which VRM may be formed, followed if need be by forming Si (e.g., by epitaxial growth) over the VRM to complete the source region.

The fabrications steps may be performed in any feasible order. It also should be appreciated that a number of features described above may be “mixed and matched” to create further variations without departing from the scope of the invention.

Note that not all steps that may be performed during the manufacture of NEDMOS devices as part of an IC are shown in aforementioned figures. Such steps may vary between IC foundries and may include (but are not limited to) substrate thinning, planarization, special implantations, annealing, formation of ohmic contacts, and formation of additional temporary or permanent structures (e.g., drift regions, substrate contacts, passivation layers, salicide blocks, replacement metal gate (RMG)), etc. After formation of a basic MOSFET structure, back-end-of-line (BEOL) processes may be applied, such as fabrication of electrical contacts (pads), vias, insulating layers (dielectrics), metallization layers, and bonding sites for die-to-package connections.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

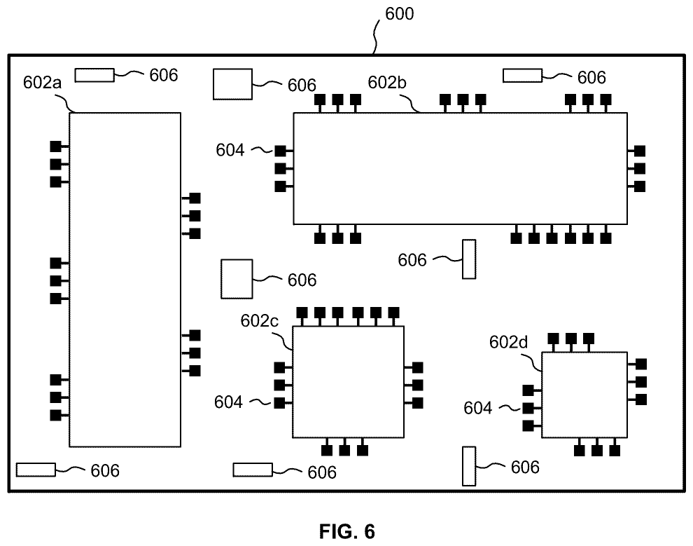

As one example of further integration of embodiments of the present invention with other components, FIG. 6 is a top plan view of a substrate 600 that may be, for example, a printed circuit board or chip module substrate (e.g., a thin-film tile). In the illustrated example, the substrate 600 includes multiple ICs 602a-602d having terminal pads 604 which would be interconnected by conductive vias and/or traces on and/or within the substrate 600 or on the opposite (back) surface of the substrate 600 (to avoid clutter, the surface conductive traces are not shown and not all terminal pads are labelled). The ICs 602a-602d may embody, for example, signal switches, active and/or passive filters, amplifiers (including one or more LNAs), and other circuitry. For example, IC 602b may incorporate one or more instances of a NEDMOS FET, LDMOS FET, and/or Extended Drain CMOS FET pair fabricated in accordance with the teachings of this disclosure.

The substrate 600 may also include one or more passive devices 606 embedded in, formed on, and/or affixed to the substrate 600. While shown as generic rectangles, the passive devices 606 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 600 to other passive devices 606 and/or the individual ICs 602a-602d. The front or back surface of the substrate 600 may be used as a location for the formation of other structures.

Embodiments of the present invention are useful in a wide variety of larger radio frequency (RF) circuits and systems for performing a range of functions, including (but not limited to) RF power amplifiers, RF low-noise amplifiers (LNAs), antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies that exhibit the floating body effect, including BiCMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly MOSFETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An extended drain metal-oxide-semiconductor (EDMOS) field-effect transistor (FET) including an active layer that includes:
(a) a body region having a source-side edge and a drain-side edge;
(b) a source region adjacent the source-side edge of the body region, the source region including at least one layer of Si and at least one layer of a built-in voltage (Vbi) reduction material;
(c) a drift region having a first side adjacent the drain-side edge of the body region, and having a second side; and
(d) a drain region adjacent the second side of the second drift region.

2. The EDMOS FET of claim 1, wherein the Vbi reduction material comprises at least one of germanium, a heterogeneous or homogenous silicon germanium alloy, and/or a heterogeneous or homogenous indium arsenide alloy.

3. The EDMOS FET of claim 1, wherein the active layer includes a thin channel region and abutting thick edge regions.

4. The EDMOS FET of claim 1, further including at least one body contact region formed through the source region.

5. The EDMOS FET of claim 1, wherein the body region is doped with a first dopant, and the source region and drain region are doped with a second dopant of opposite polarity to the first dopant.

6. The EDMOS FET of claim 1, wherein the body region is intrinsic Si.

7. The EDMOS FET of claim 1, wherein the EDMOS FET is an N-type EDMOS FET.

8.-9. (canceled)

10. An N-type extended drain metal-oxide-semiconductor (NEDMOS) field-effect transistor (FET) including a Si active layer that includes:
(a) a body region having a source-side edge and a drain-side edge;
(b) an N+ source region adjacent the source-side edge of the body region, the N+ source region including at least one layer of N+ Si and at least one layer of an N+ built-in voltage (Vbi) reduction material;
(c) an N− drift region having a first side adjacent the drain-side edge of the body region, and having a second side; and
(d) an N+ drain region adjacent the second side of the N− drift region.

11. The NEDMOS FET of claim 10, wherein the Vbi reduction material comprises at least one of germanium, a heterogeneous or homogenous silicon germanium alloy, and/or a heterogeneous or homogenous indium arsenide alloy.

12. The NEDMOS FET of claim 10, wherein the Si active layer includes a thin channel region and abutting thick edge regions.

13. The NEDMOS FET of claim 10, further including at least one P+ body contact region formed through the N+ source region.

14. The NEDMOS FET of claim 10, wherein the body region is intrinsic Si.

15.-16. (canceled)

17. A method of fabricating an extended drain metal-oxide-semiconductor (EDMOS) field-effect transistor (FET), including:
(a) forming, within a semiconductor active layer, a body region having a source-side edge and a drain-side edge;
(b) forming a source region adjacent the source-side edge of the body region, the source region including at least one layer of Si and at least one layer of a Vbi reduction material;
(c) forming a drift region having a first side adjacent the drain-side edge of the body region, and having a second side;
(d) forming a drain region adjacent the second side of the drift region;
wherein the steps of forming may be performed in any feasible order.

18. The method of claim 17, further including forming a gate structure on the semiconductor active layer and overlying the body region.

19. The method of claim 17, wherein the Vbi reduction material comprises at least one of germanium, a heterogeneous or homogenous silicon germanium alloy, and/or a heterogeneous or homogenous indium arsenide alloy.

20. The method of claim 17, wherein the semiconductor active layer includes a thin channel region and abutting thick edge regions.

21. The method of claim 17, further including at least one body contact region formed through the source region.

22. The method of claim 17, wherein the body region is doped with a first dopant, and the source region and drain region are doped with a second dopant of opposite polarity to the first dopant.

23. The method of claim 17, wherein the body region is intrinsic Si.

24. The method of claim 17, wherein the EDMOS FET is an N-type EDMOS FET.

25. (canceled)
